(19) United States
(12) Patent Application Publication
(10) Pub. No.: US 2019/0250208 A1
(43) Pub. Date: Aug. 15, 2019

(54) APPARATUS AND METHOD FOR DETECTING DAMAGE TO AN INTEGRATED CIRCUIT

(71) Applicant: QUALCOMM Incorporated, San Diego, CA (US)

(72) Inventors: Vijayakumar DHANASEKARAN, San Diego, CA (US); Qubo ZHOU, San Diego, CA (US); Lennart Karl-Axel MATHE, San Diego, CA (US)

(21) Appl. No.: 15/892,739

(22) Filed: Feb. 9, 2018

(51) Int. Cl. G01R 31/28; H01L 49/02; H01L 29/92; H01L 23/58; H01L 21/66

(52) U.S. Cl. CPC G01R 31/2884; H01L 28/20; H01L 29/92; G01R 31/2896; H01L 22/34; H01L 22/32; H01L 23/585

(57) ABSTRACT

Various features relate to a test ring including an integrated circuit. The test ring is located around a periphery of the integrated circuit. The test ring includes a first terminal, a second terminal, and a first circuit element, wherein the first terminal is coupled to the first circuit element, and the first circuit element is coupled to the second terminal, wherein the first terminal, the first circuit element and the second terminal are coupled together in series.

### BACKGROUND

### Field of the Disclosure

Various features relate to a test ring in an integrated circuit.

### Background

Integrated circuits (IC) are susceptible to mechanical damage during fabrication, such as during de-bonding of a carrier wafer, and during sawing or dicing. Mechanical damage may also occur during handling, shipping, tape and reel interaction, during pick and place of surface mounted devices onto or near the IC, and during board flex. Wafer level package IC's are also susceptible to mechanical damage due to lack of protection around the IC. Mechanical damage that occurs during pick and place of surface mounted devices may not be found until phone level testing. Mechanical damage found during phone level testing requires disassembly and reassembly of phone components which can be costly.

FIG. 1 illustrates a top-view of a conventional seal ring. The seal ring 102 is located around a perimeter of an IC 100 and surrounds circuitry (not shown) of the IC 100. The seal ring 102 is integrated into the IC 100 and includes metals such as contacts and vias (not shown) that are part of the IC 100. The seal ring 102 prevents damage to the IC 100, such as cracking, that may result from mechanical stress or from environmental stresses (such as moisture).

Although the seal ring 102 prevents damage to the IC 100, it does not detect whether the IC 100 is damaged (e.g., cracked), nor does it provide information on where the damage is located on the IC 100. There is a need for an apparatus that can detect whether the IC 100 is damaged.

### SUMMARY

Various features relate to a test ring. In a first example, an apparatus comprises a test ring around a periphery of an integrated circuit (IC). The test ring further includes a first terminal, a second terminal, and a first circuit element, wherein the first terminal is coupled to the first circuit element, and the first circuit element is coupled to the second terminal, wherein the first terminal, the first circuit element and the second terminal are coupled together in series.

In a second example, a method for detecting damage to the IC, comprises enabling a tester that is coupled to a test ring in a periphery of an integrated circuit (IC), the test ring comprises a first circuit element coupled in series to a first terminal and a second terminal, measuring a value with the tester, comparing the measured value with a reference value, and determining that there is damage to the IC if the measured value is about not equal to the reference value, or determining that there is not damage to the IC if the measured value is about equal to the reference value.

In a third example, an apparatus comprises a test ring around a periphery of an integrated circuit (IC), the test ring further comprises a first terminal, a second terminal, a first means for detecting damage to the IC, coupled in series with the first terminal and the second terminal.

### DRAWINGS

Various features, nature and advantages may become apparent from the detailed description set forth below when taken in conjunction with the drawings in which like reference characters identify correspondingly throughout.

FIG. 1 illustrates a top-view of a conventional seal ring.

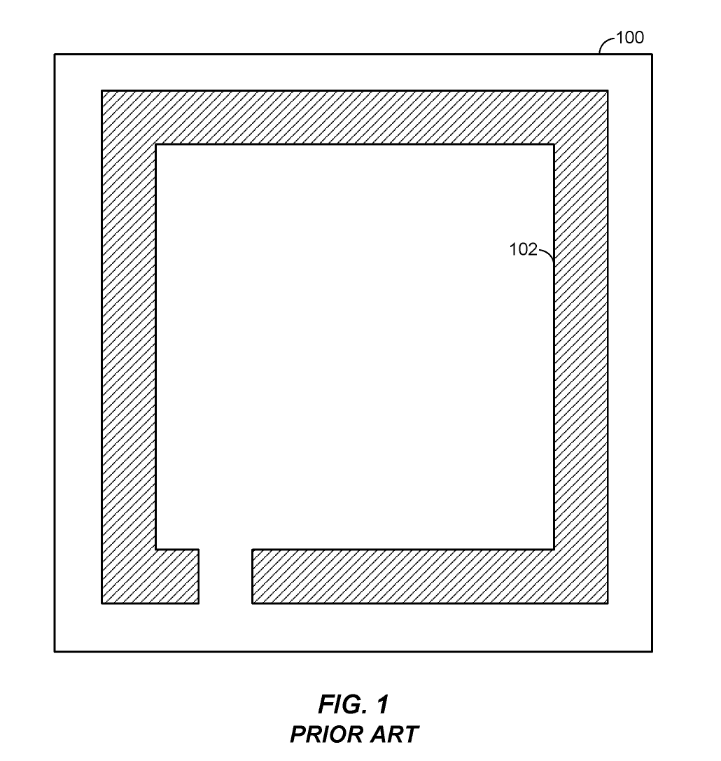

FIG. 2A illustrates a top-view of an exemplary test ring in an integrated circuit.

FIG. 2B illustrates a cross-section of the exemplary test ring of FIG. 2A.

FIG. 3A illustrates a top-view of an exemplary test ring in an integrated circuit.

FIG. 3B illustrates a cross-section of the test ring of FIG. 3A.

FIG. 4 illustrates a top-view of an exemplary test ring in an integrated circuit.

FIG. 5 illustrates a top-view of an exemplary test ring in an integrated circuit.

FIG. 6A illustrates an exemplary method for detecting damage to an integrated circuit.

FIG. 6B illustrates a tester for detecting damage to an IC.

FIG. 6C illustrates a structure for use with the exemplary method of detecting damage to an IC.

FIG. 7 illustrates various electronic devices that may include the various substrates, integrated devices, integrated device packages, semiconductor devices, dies, integrated circuits, packages, or inductors described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams to avoid obscuring the aspects in unnecessary detail. In other instances, well-known circuits, structures and techniques may not be shown in detail in order not to obscure the aspects of the disclosure.

### Overview

Some features pertain to a test ring formed around a periphery of an integrated circuit (IC). The test ring is integrated into the IC. The test ring may be located in a seal ring located around a periphery of the IC and may be used to detect damage (e.g., detect a crack) to the IC. In one aspect, the test ring may be used to detect a first damaged location of the IC. The test ring allows for detection of damage to the IC, even after the IC has been assembled into a final product (e.g., mobile device/phone, laptop, wearable). This results in cost savings from avoiding de-assembly of the final product.

The test ring includes a circuit element (or more than one circuit element), where the circuit element may be a resistor, a capacitor, a flip-flop, or inverter. A first terminal of the test ring is coupled to the first circuit element, and the first circuit element is coupled to a second terminal of the test ring. That is, the first and second terminal, and the first circuit element are coupled together in series.

A method for detecting damage to the IC includes enabling a tester that is coupled to the test ring in a periphery of the IC, measuring a value with the tester, comparing the measured value with the reference value, and determining that the IC is damaged if the measured value is about not equal to the reference value, or determining that the IC is not damaged if the measured value is about equal to the reference value.

The tester may be an integrated into the IC (i.e., integrated tester) or external to the IC (i.e., external tester) and may include a signal generator for generating a reference value, a measuring device, a comparator, logic, and memory.

### Exemplary Test Ring Comprising Passive Circuit Elements in an Integrated Circuit

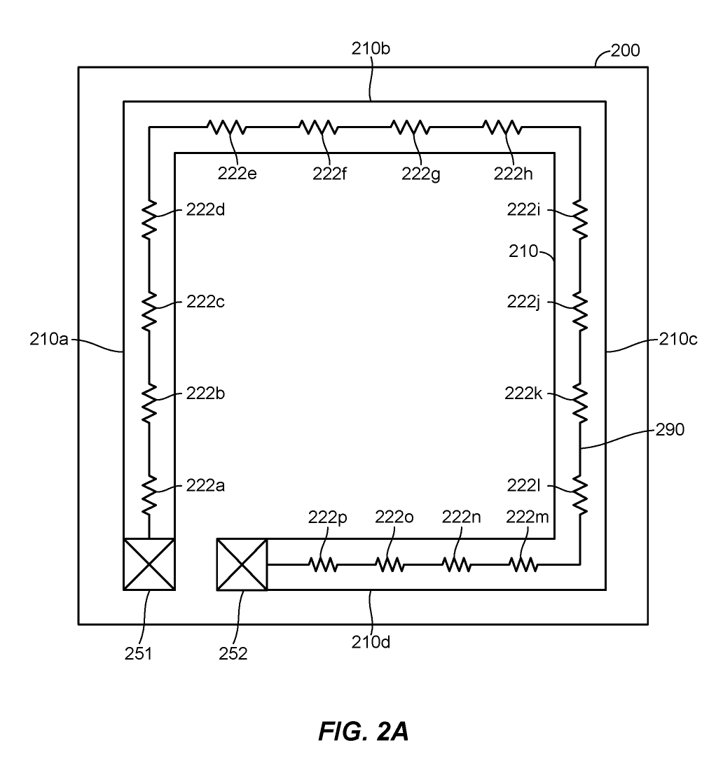

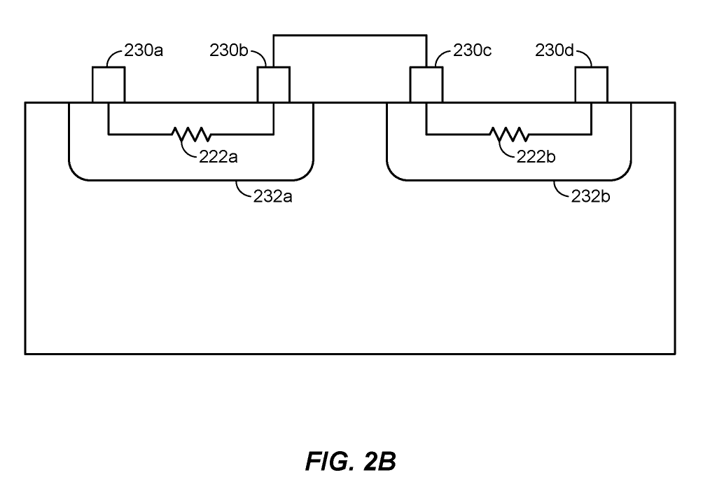

FIG. 2A illustrates a top-view of an exemplary test ring in an IC.

Specifically, FIG. 2A illustrates a test ring 290 around a periphery of an IC 200, the test ring 290 is used to detect damage to the IC 200 (such as a crack). The test ring includes a plurality of circuit elements 222 coupled together in series with a first terminal 251 and a second terminal 252. The plurality of circuit elements 222 may be passive devices (passive devices are devices that do not require power to operate). In one aspect, the plurality of circuit elements 222 are a plurality of resistors 222a-p (e.g., first means for detecting damage to the IC). The plurality of resistors 222a-p may be integrated into the IC 200 (see discussion for FIG. 2B).

The test ring 290 is located in a seal ring 210 around a periphery of the IC 200. The seal ring 210 has a first side 210a, a second side 210b, a third side 210c, and a fourth side 210d. FIG. 2A illustrates a first 222a, a second 222b, a third 222c, and a fourth resistor 222d on a first side 210a of the seal ring 210, a fifth 222e, a sixth 222f, a seventh 222g, and an eighth resistor 222h on a second side 210b of the seal ring 210, a ninth 222i, a tenth 222j, an eleventh 222k, and a twelfth resistor 222l on a third side 210c of the seal ring 210, and a thirteenth 222m, a fourteenth 222n, a fifteenth 222o and a sixteenth resistor 222p on a fourth side 210d of the seal ring 210.

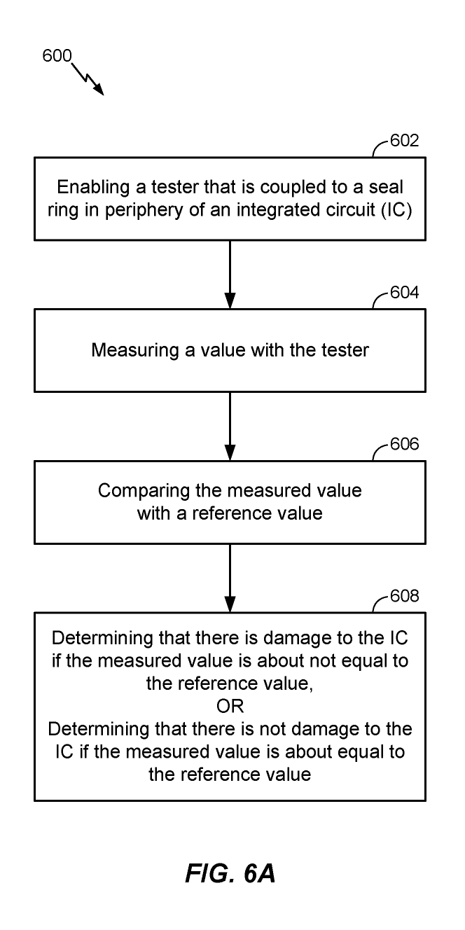

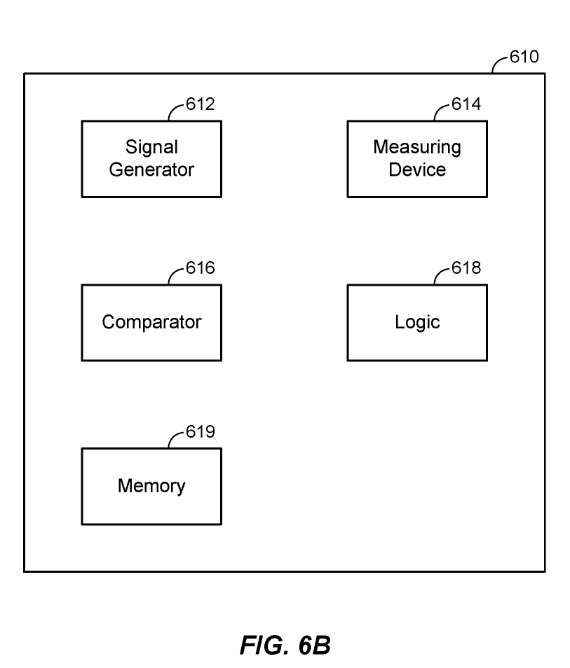

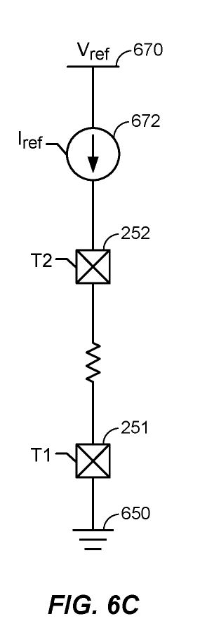

The plurality of resistors 222a-p are coupled in series, where a first end of the first resistor 222a is coupled to the first terminal 251, a second end of the first resistor 222a is coupled to a first end of the second resistor 222b, a second end of the second resistor 222c is coupled to a first end of the third resistor 222c, and so on, until we come to the second end of the sixteenth resistor 222p that is coupled to the second terminal 252. Together, the plurality of resistors 222a-p form an equivalent resistance. The equivalent resistance for resistors in series can be found by adding the resistance values of each of the plurality of resistors 222a-p. Accordingly, R_{equivalant}=R₂₂₂ₐ+R_{222b}+R_{222c}+R_{222d}+R₂₂₂ₑ+R_{222f}+R_{222g}+R₂₂₂ₕ+R₂₂₂ᵢ+R₂₂₂ⱼ+R₂₂₂ₖ+R₂₂₂ₗ+R₂₂₂ₘ+R₂₂₂ₙ+R₂₂₂ₒ+R₂₂₂ₚ. The use of the equivalent resistance, R_{equivalant}, will be discussed later with respect to FIG. 6A.

A total of sixteen resistors are shown (of a plurality of resistors 222a-p), four resistors on each side (first side 210a, second side 210b, third side 210c, and fourth side 210d) of the seal ring 210, however, this disclosure is not so limited. More resistors or less resistors may be used, and they may be allocated or spread across the seal ring 210 in a different configuration that what is shown in FIG. 2A.

In one aspect, there may be a single resistor such as the first resistor 222a. The first resistor 222a (and only resistor in this aspect) may be located on any one of the first 210a, second 210b, third 210c, or fourth side 210d of the seal ring 210. In another aspect, the seal ring 210 may only have a first resistor 222a (i.e. a first circuit element) and a second resistor 222b (i.e., a second circuit element). In this aspect, each one of the first resistor 222a or the second resistor 222b or both, may be located on the first side 210a, or the second side 210b, or the third side 210c, or the fourth side 210d of the seal ring 210. In another aspect, the plurality of resistors 222a-p may include sixteen resisters 222a-p, with two resistors (e.g., 222a,b) on a first side 210a of the seal ring 210, eight resistors (e.g., 222c-j) on a second side 210b of the seal ring 210, and six resistors (e.g. 222i-p) on a third side 210c of the seal ring 210. In this aspect, there are no resistors on the fourth side 210d of the seal ring 210.

FIG. 2B illustrates a cross-section of the test ring 290 of FIG. 2A, including a portion of the IC 200. For clarity, only a portion of the IC 200 is shown. The IC 200 may have other layers that are not shown.

Specifically, FIG. 2B illustrates the substrate 204. The substrate 204 is a p-type substrate. The substrate 204 includes the plurality of circuit elements 222, including the plurality of resistors 222a-p. For clarity, only the first resistor 222a and the second resistor 222b are shown. The first resistor 222a is formed by the following: a first metal 230a and a second metal 230b located in a first lateral plane over the substrate 204, and over a first isolation region 232a. The first isolation region 232a separates the first metal 230a and the second metal 230b, thereby creating the first resistor 222a integrated into the IC 200. It shall be understood that the resistor 222a in FIG. 2B is illustrative only, that is, the drawn resistor is not actually present, but is representative of the resistance created by the structure shown in FIG. 2B.

Similarly, the second resistor 222b is formed by the following: a third metal 230c and a fourth metal 230d located in the lateral plane over the substrate 204, and over a second isolation region 232b. The second isolation region 232b separates the third metal 230c and the second metal 230d, thereby creating the second resistor 222b integrated into the IC 200. It shall be understood that the resistor 222b in FIG. 2B is illustrative only, that is, the drawn resistor is not actually present, but is representative of the resistance created by the structure shown in FIG. 2B.

As mentioned previously, the first resistor 222a and the second resistor 222b are coupled in series. This is accomplished by coupling the second metal 230b (e.g., the second end of the first resistor 222a) to the third metal 230c (e.g., the first end of the second resistor 222b).

Although FIG. 2B illustrates the substrate 204 as a p-type substrate, and the first 232a and second isolation regions 232b as being n-well type isolation regions, this disclosure is not so limited. The substrate 204 may be any type of substrate such as a n-type substrate or deep n-well substrate. Moreover, the first isolation region 232a and the second isolation region 232b may be any type of isolation region such as p-well or some other hybrid, such that an integrated resistor is formed. Moreover, the plurality of resistors 222a-p may be formed as a well-resistor, a polysilicon resistor, or a metal resistor.

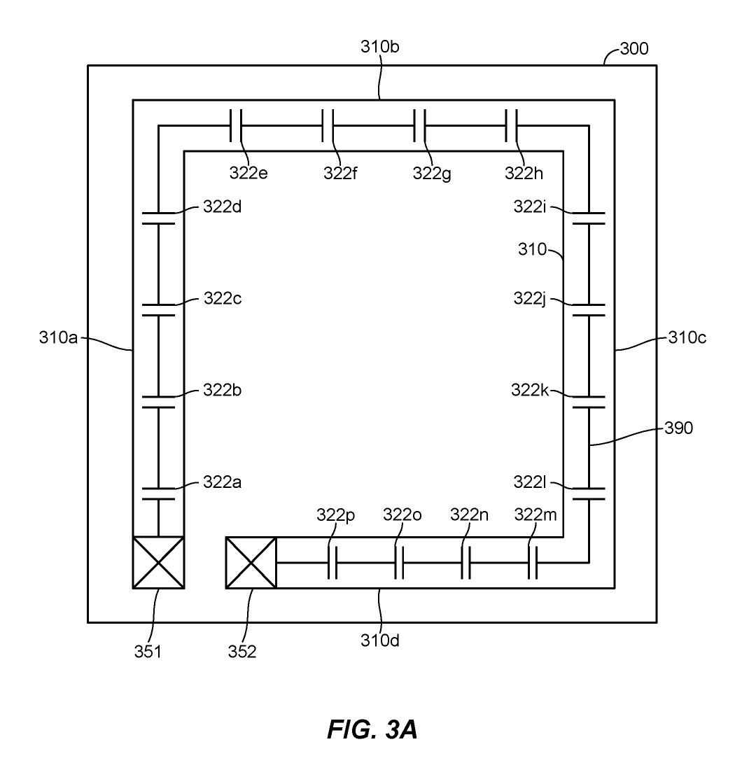

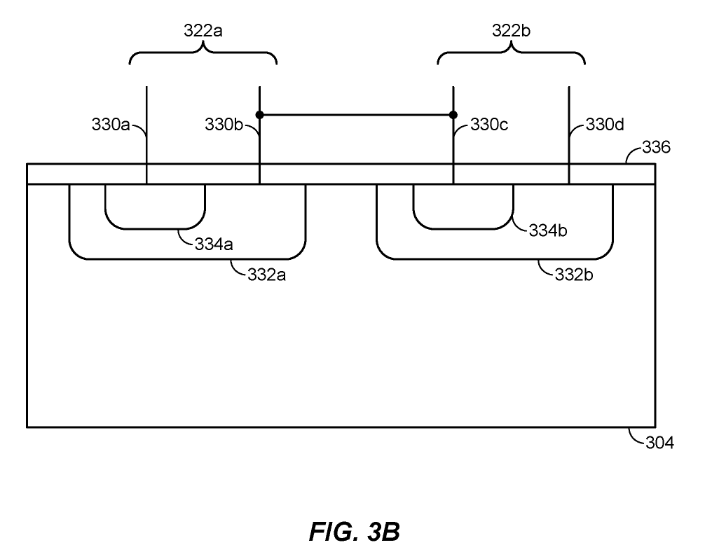

FIG. 3A illustrates a top-view of an exemplary test ring in an IC. Specifically, FIG. 3A illustrates a test ring 390 around a periphery of an IC 300, the test ring 390 is used to detect damage to the IC 300 (such as a crack). The test ring 390 includes a plurality of circuit elements 322 coupled together in series with a first terminal 351 and a second terminal 352. The plurality of circuit elements 322 may be passive devices. In one aspect, the plurality of circuit elements 322 are a plurality of capacitors 322a-p (e.g., first means for detecting damage to the IC). The plurality of capacitors 322a-p may be integrated into the IC 300 as will be explained later with respect to FIG. 3B.

The test ring 390 is located in a seal ring 310 around a periphery of the IC 300. The seal ring 310 has a first side 310a, a second side 310b, a third side 310c, and a fourth side 310d. FIG. 3A illustrates a first 322a, a second 322b, a third 322c, and a fourth capacitor 322d on a first side 310a of the seal ring 310, a fifth 322e, a sixth 322f, a seventh 322g, and an eighth capacitor 322h on a second side 310b of the seal ring 310, a ninth 322i, a tenth 322j, an eleventh 322k, and a twelfth capacitor 322l on a third side 310c of the seal ring 310, and a thirteenth 322m, a fourteenth 322n, a fifteenth 322o and a sixteenth capacitor 322p on a fourth side 310d of the seal ring 310.

The plurality of capacitors 322a-p are coupled in series, where a first end of the first capacitor 322a is coupled to the first terminal 351, a second end of the first capacitor 322a is coupled to a first end of the second capacitor 322b, a second end of the second capacitor 322c is coupled to a first end of the third capacitor 322c, and so on, until we come to the second end of the sixteenth capacitor 322p that is coupled to the second terminal 352. Together, the plurality of capacitors 322a-p form an equivalent capacitance. The equivalent capacitance for capacitors is as follows: the reciprocal value of the equivalent capacitance is equal to the sum of reciprocal capacitance values for each of the plurality of capacitors 322a-p. Accordingly, 1/C_{equivalent}=1/C₃₂₂ₐ+1/C_{322b}+1/C_{322c}+1/C_{322d}+1/C₃₂₂ₑ+1/C_{322f}+1/C_{322g}+1/C₃₂₂ₕ+1/C₃₂₂ᵢ+1/C₃₂₂ⱼ+1/C₃₂₂ₖ+1/C₃₂₂ₗ+1/C₃₂₂ₘ+1/C₃₂₂ₙ+1/C₃₂₂ₒ+1/C₃₂₂ₚ. The equivalent capacitance, C_{equivalent}, will be discussed later with respect to FIG. 6A.

A total of sixteen capacitors are shown (of a plurality of capacitors 322a-p), four capacitors on each side (first side 310a, second side 310b, third side 310c, and fourth side 310d) of the seal ring 310, however, this disclosure is not so limited. More capacitors or less capacitors may be used, and they may be allocated or spread across the seal ring 310 in a different configuration that what is shown in FIG. 3A.

In one aspect, there may be a single capacitor such as first capacitor 322a. The first capacitor 322a (and only capacitor in this aspect) may be located on any one of the first 310a, second 310b, third 310c, or fourth side 310d of the seal ring 310. In another aspect, the seal ring 310 may only have a first capacitor 322a (i.e. a first circuit element) and a second capacitor 322b (i.e., a second circuit element). In this aspect, each one of the first capacitor 322a or the second capacitor 322b or both, may be located on the first side 310a, or the second side 310b, or the third side 310c, or the fourth side 310d of the seal ring 310. In another aspect, the plurality of capacitors 322a-p may include sixteen capacitors 322a-p, with two capacitors (e.g., 322a, b) on a first side 310a of the seal ring 310, eight capacitors (e.g., 322c-j) on a second side 310b of the seal ring 310, and six capacitors (e.g. 322i-p) on a third side 310c of the seal ring 310. In this aspect, there are no capacitors on the fourth side 310d of the seal ring 310.

FIG. 3B illustrates a cross-section of the test ring 390 of FIG. 3A, including a portion of the IC 200. For clarity, only a portion of the IC 300 is shown. The IC 300 may have other layers that are not shown.

Specifically, FIG. 3B illustrates a substrate 304. The substrate 304 is a p-type substrate. The substrate 304 includes the plurality of circuit elements 322, including the plurality of capacitors 322a-p. For clarity, only the first capacitor 322a and the second capacitor 322b are shown. The substrate 304 includes a plurality of isolation regions 332 including a first isolation region 332a and a second isolation region 332b. The plurality of isolation regions 332 may include a plurality of oppositely doped areas including a first oppositely doped area 334a and a second oppositely doped area 334b. In one aspect, the first isolation region 332a and the second isolation region 332b are an n-well, and the first oppositely doped area 334a and the second oppositely doped area 334b are P-type. The substrate 304 may have an isolation layer 336 over the top of the substrate 304.

The first capacitor 322a is formed by the following: a first metal 330a coupled through the isolation layer 336 to the first oppositely doped area 334a, and a second metal 330b coupled through the isolation layer 336 to the first isolation region 332a. The first metal 330a is configured to operate as a first electrode of the capacitor 322a and the second metal 330b is configured to operate as a second electrode of the first capacitor 322a.

Similarly, the second capacitor 322b is formed by the following: a third metal 330c coupled through the isolation layer 336 to the second oppositely doped area 334b, and a fifth metal 330d coupled through the isolation layer 336 to the second isolation region 332b. The third metal 330c is configured to operate as a first electrode of the second capacitor 322b and the fourth metal 330d is configured to operate as a second electrode of the second capacitor 322b.

As mentioned previously, the first capacitor 322a and the second capacitor 322b are coupled in series. This is accomplished by coupling the second metal 330b (e.g., the second end of the first capacitor 322a) to the third metal 330c (e.g., the first end of the second capacitor 322b). Although FIG. 3B illustrates the first capacitor 322a and the second capacitor 3222b as being formed in the substrate 304 as a p-type substrate, the first 332a and second isolation regions 332b as being n-well type isolation regions, and the first 334a oppositely doped area and the second oppositely doped area 334b as being of p-type, this disclosure is not so limited. The plurality of capacitors 322a-p may be formed as junction capacitors, MOS capacitors or metal capacitors as non-limiting examples. Moreover, the first isolation region 332a and the second isolation region 332b may be any type of isolation region such as p-well or some other hybrid, such that an integrated capacitor is formed.

### Exemplary Test Ring Comprising Active Circuit Elements in an Integrated Circuit

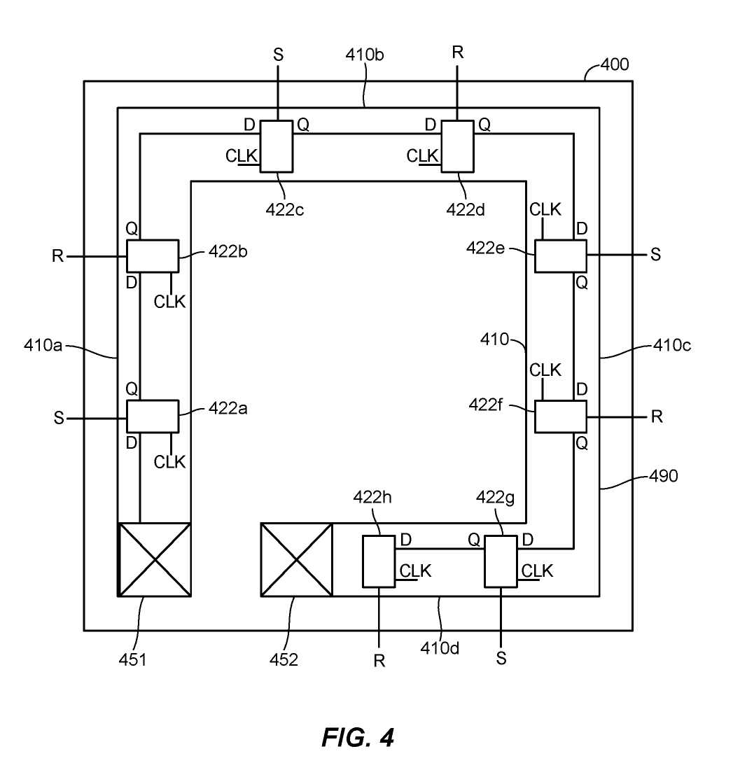

FIG. 4 illustrates a top-view of an exemplary test ring in an IC. Specifically, FIG. 4 illustrates a test ring 490 around a periphery of an IC 400, the test ring 490 is used to detect damage to the IC 400 (such as a crack). Moreover, the test ring 490 is used to determine a first damaged location of the IC 400 (e.g., a first crack location).

The test ring 490 includes a plurality of circuit elements 422 coupled together in series with a first terminal 451 and a second terminal 452. In one aspect, the plurality of circuit elements 422 are active devices (where active devices require a power source to operate). In one aspect, the plurality of circuit elements 422 are a plurality of flip-flops 422a-h (e.g., first means for detecting damage to the IC, e.g., means for determining a first damaged location of the IC). The plurality of flip-flops 422a-h are integrated into the IC 400.

The test ring 490 is located in a seal ring 410 around a periphery of the IC 400. The seal ring 410 has a first side 410a, a second side 410b, a third side 410c, and a fourth side 410d. FIG. 4 illustrates a first flip-flop 422a and a second flip-flop 422b on a first side 410a of the seal ring 410, a third flip-flop 422c and fourth flip-flop 422d on a second side 410b of the seal ring 410, a fifth flip-flop 422e and sixth flip-flop 422f on a third side 410c of the seal ring 410, and a seventh flip-flop 422g and eighth flip-flop 422h on a fourth side 410d of the seal ring 410.

The plurality of flip-flops 422a-h are coupled in series, where a first end (e.g., the input D) of the first flip-flop 422a is coupled to the first terminal 451, a second end (e.g., the output Q) of the first flip-flop 422a is coupled to a first end (e.g., the input D) of the second flip-flop 422b, a second end (e.g., the output Q) of the second flip-flop 422c is coupled to a first end (e.g., the input D) of the third flip-flop 422c, and so on, until we come to the second end (e.g., the output Q) of the eighth flip-flop 222h that is coupled to the second terminal 452. Moreover, each of the plurality of flip-flops 422a-h receives a clock as an input.

A total of eight flip-flops are shown (of the plurality of flip-flops 422a-h), two flip-flops on each side (first side 410a, second side 410b, third side 410c, and fourth side 410d) of the seal ring 410, however, this disclosure is not so limited. More flip-flops or less flip-flops may be used, and they may be allocated or spread across the seal ring 410 in a different configuration that what is shown in FIG. 4.

In one aspect, there may be a single flip-flop such as the first flip-flop 422a. The first flip-flop 422a (and only flip-flop in this aspect) may be located on any one of the first 410a, second 410b, third 410c, or fourth side 410d of the seal ring 410. In another aspect, the seal ring 410 may only have a first flip-flop 422a (i.e. a first circuit element) and a second flip-flop 422b (i.e., a second circuit element). In this aspect, each one of the first flip-flop 422a or the second resistor 422b or both, may be located on the first side 410a, or the second side 410b, or the third side 410c, or the fourth side 410d of the seal ring 410. In another aspect, the plurality of flip-flops 422 may include sixteen flip-flops 422a-p (not all shown), with two flip-flops (e.g., 422a, b) on a first side 410a of the seal ring 410, eight flip-flops (e.g., 422c-j) on a second side 410b of the seal ring 410, and six flip-flops (e.g. 422i-p) on a third side 410c of the seal ring 410. In this aspect, there are no flip-flops on the fourth side 410d of the seal ring 410.

The number of flip-flops such as 422a-h and their location on the seal ring 410 will affect the precision in determining the location in the seal ring 410. The less distance there is between two adjacent flip-flops (e.g., 422a and 422b, or 422b and 422c, or 422g and 422h, etc.) of the plurality of flip-flops 422a-h, the more precisely the first damaged location (e.g., first cracked location) of the IC 400 may be determined.

In one aspect, where there is only a single flip-flop 422a in the seal ring 410, damage to the IC 400 (e.g., a crack) may be determined, however the location of the damage may be anywhere on the IC 400. In another aspect, the seal ring 410 has only two flip-flops 422a, and 422b equally spaced apart in the seal ring 410. The first flip-flop 422a corresponds to a first portion (i.e., a three-dimensional portion) of the IC 400 and the second flip-flop 422b corresponds to a second portion (i.e., a three-dimensional portion) of the IC 400. A first damaged location (e.g., crack) of the IC 400 may be determined as either occurring in the first portion or a second portion of the IC 400. In another aspect, where there are fifty flip-flops in the IC 400 (not shown), a first damaged location of the IC 400 may be determined as occurring between one of the fifty flip flops (i.e., in one of the fifty regions of the IC corresponding to the fifty flip-flops), thereby adding more precision in determining the crack location. The method of detecting the first damaged location of the IC (e.g., 400) will be described later with respect to FIG. 6A.

FIG. 4 illustrates the plurality of flip-flops 422a-h as being S—R type of flip-flops. However, any type of flip-flop may be utilized. For example, a T flip-flop, a J-K flip-flop or a D flip-flop may be used instead. The plurality of circuit elements 422 such as the plurality of flip-flops 422a-h may be integrated into the IC 400 through methods such as through integrated logic gates such as AND, NOR or NAND logic gates or a combination (not shown). The integrated logic gates are connected in series as previously explained. Such integrated logic gates may be implemented in a substrate of the IC 400, utilizing metal layers, and isolation regions including doped areas (not shown). The substrate (not shown) may be any type of substrate such as a n-type or p-type substrate, and the isolation regions (not shown) and doped areas may be any type (e.g., n or p), such that a flip-flop may be formed.

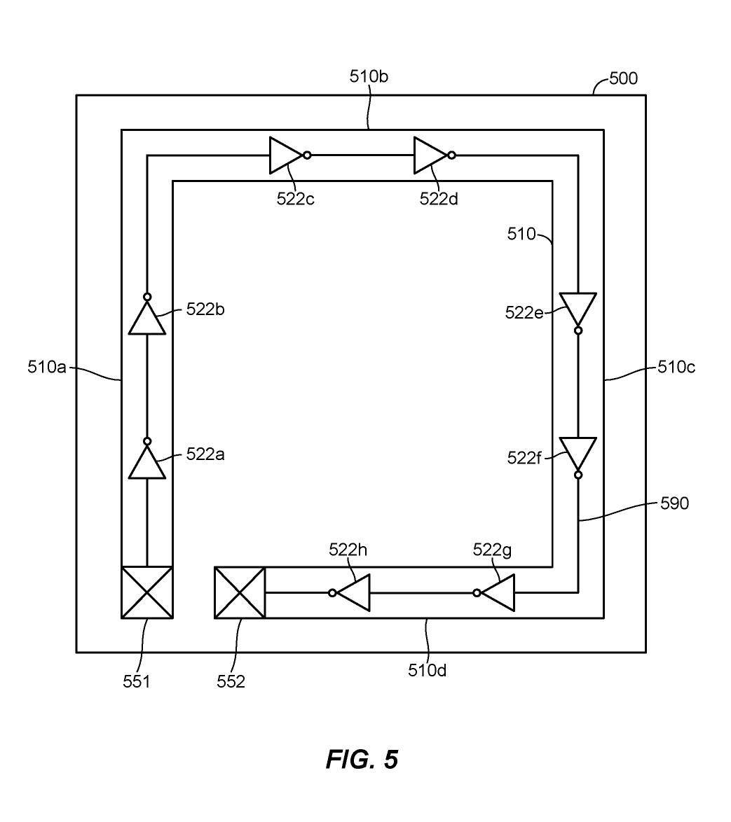

FIG. 5 illustrates a top-view of an exemplary test ring. Specifically, FIG. 5 illustrates a test ring 590 around a periphery of an IC 500, the test ring 590 is used to detect damage to the IC 500 (such as a crack). The test ring 590 includes a plurality of circuit elements 522 coupled together in series with a first terminal 551 and a second terminal 552. The plurality of circuit elements 522 may be active devices. In one aspect, the plurality of circuit elements 522 are a plurality of inverters 522a-h (e.g., first means for detecting damage to the IC) integrated into the IC 500.

The test ring 590 is located in a seal ring 510 around a periphery of the IC 500. FIG. 5 illustrates a first inverter 522a and a second inverter 522b on a first side 510a of the seal ring 510, a third inverter 522c and fourth inverter 522d on a second side 510b of the seal ring 510, a fifth inverter 522e and sixth inverter 522f on a third side 510c of the seal ring 510, and a seventh inverter 522g and eighth inverter 522h on a fourth side 510d of the seal ring 510.

The plurality of inverters 522a-h are coupled in series, where a first end of the first inverter 522a is coupled to the first terminal 551, a second end of the first inverter 522a (e.g., output of the first inverter 522a) is coupled to a first end of the second inverter 522b (e.g., input of the first inverter 522a), a second end of the second inverter 522c is coupled to a first end of the third inverter 522c, and so on, until we come to the second end of the eighth inverter 222h that is coupled to the second terminal 552. More inverters or less inverters may be used than what is illustrated in FIG. 5, and they may be allocated or spread across the seal ring 510 in a different configuration that what is shown in FIG. 5. In one aspect, the seal ring 510 may only have a first inverter 522a. In another aspect, the seal ring 510 may only have a first inverter 522a and a second inverter 522b.

The plurality of circuit elements 522 such as the plurality of inverters 522a-h may be integrated into the IC 500 including a substrate of the IC 500, metal layers, and isolation regions including doped areas (not shown). The substrate (not shown) may be any type of substrate such as a n-type or p-type substrate, and the isolation regions (not shown) and doped areas may be any type (e.g., n or p), such that an inverter may be formed.

Exemplary Method for Detecting Damage in an Integrated Circuit with an Exemplary Test Ring

FIG. 6A illustrates an exemplary method for detecting damage (e.g., a crack) in an IC. It should be noted that for clarity and simplification, in some instances, several steps may have been combined into a single step. FIG. 6B illustrates a tester 610 for detecting damage (e.g., a crack) to an IC (e.g., 200, 300, 400, or 500).

In one aspect, the tester 610 is an external tester, that is, a tester that is not integrated into the IC (e.g., IC 200, 300, 400, or 500). In this aspect, the first terminal (e.g., 251, 351, 451, or 551) and the second terminal (e.g., 252, 352, 452, or 552) may be coupled to an interconnect (e.g., solder ball, pillar) of the IC (e.g., 200, 300, 400, or 500). In another aspect, the tester 610 is an integrated tester, that is, integrated into or on the IC. Regardless of whether the tester 610 is an external tester or an integrated tester, the tester 610 is coupled to a test ring (e.g., 290, 390, 490, or 590) located in a periphery of the integrated circuit (e.g., 200, 300, 400, or 500). The tester 610 in FIG. 6B may comprise components such as a signal generator 612, a measuring device 614, a comparator 616, logic 618 and memory 619. Although these components are shown separately in FIG. 6B, the components may be combined or omitted (for example, if the function of the component is performed manually, then that component may be omitted from the tester 610).

In some aspects, the signal generator 612 may be a clock, a sinusoidal signal generator, or a digital signal generator. The measuring device 614 is configured to measure a value (i.e., the measured value) such as a resistance, a voltage, or a pattern. The memory 619 is configured to store a reference value, where the reference value may be a resistance, a voltage, or a pattern. The comparator 616 is configured to compare the measured value to the reference value. The logic 618 is configured to determine whether there is a damage to the IC (e.g., a crack). In one aspect, the logic 618 may determine there is a crack if the measured value is about not equal to the reference value. In another aspect, the logic 618 may determine that there is not a crack if the measured value is about equal to the reference value. The logic 618 may be a circuit or an algorithm.

Devices such as the tester 610, the measuring device 614 and other devices used for measuring (e.g. voltmeters, multimeters etc.) have a tolerance range, that is, a permissible range of error. For example, such devices may have a tolerance range of approximately +/−1%. It shall be understood, the term “about”, as used in the context of about equal, or about not equal, includes the permissible range of error.

Returning to the method 600 of FIG. 6A, the method at step 602 includes enabling the tester 610. Enabling the tester 610 may include storing a reference value into the memory 619. The method at step 604 includes measuring a value (i.e., the measured value) with the tester 610, such as a resistance, a voltage, or a pattern. The method at step 606 includes comparing the measured value with the reference value. The method at step 608 includes determining that there is damage to the IC if the measured value is about not equal to the reference value, or determining that there is not damage to the IC if the measured value is about equal to the reference value. In the discussion that follows, the method 600 is discussed in further detail with respect to the illustrations in FIG. 2, FIG. 3, FIG. 4, and FIG. 5.

For the test ring 290 illustrated in FIG. 2A, enabling the tester 610 (step 602) includes coupling the measuring device 614 to the first terminal 251 and the second terminal 252 of the test ring 290, and coupling one of the first terminal 251 or the second terminal 252 to ground. In one aspect, enabling the tester 610 may also include storing a reference value in a memory 619. However, it is not necessary to store the reference value in memory 619 such as in the case where the tester 610 is an external tester and the testing is being performed manually. For the test ring 290 (of FIG. 2A), the reference value is the equivalent resistance (R_{equivalant}) of the plurality of resistors (such as 222a-p). Measuring a value (i.e., the measured value) with the tester 610 (step 604) includes measuring a resistance across the first terminal 251 and the second terminal 252. The measuring device 614 may be used, or alternatively, other known methods or devices may be used to measure the value. Comparing the measured value with the reference value (e.g., R_{equivalant}) (step 606) may be done with the comparator 616.

For step 608, the logic 618 or other known methods or devices may be used for determining that there is damage to the IC 210 if the measured value is about not equal to the reference value (e.g., R_{equivalant}), or determining that there is not damage to the IC 210 if the measured value is about equal to the reference value (e.g., R_{equivalant}). In one aspect where the IC 210 is damaged (e.g., the IC 210 is cracked), the measured value would be infinite since a crack in the IC 210 would constitute an electrical open in the plurality of resistors 222a-p coupled in series. Accordingly, the measured value would about not equal to the reference value (e.g., R_{equivalant}), and the logic 618 would determine the IC 210 is damaged. In another aspect where the IC 210 is not damaged, the measured value would about equal to the reference value (e.g., R_{equivalant}), and the logic 618 would determine the IC 210 is not damaged.

In another aspect related to the test ring 290, the tester 610 is an external tester (i.e. located external to the IC). As part of enabling the tester 610 (step 602), the signal generator 612 is used to generate and apply a sinusoidal signal to the first terminal 251. The sinusoidal signal includes a reference value amplitude (i.e., the reference value). Measuring the value with the tester 610 (step 604) includes using the measuring device 614 to measure a signal at the second terminal 252, including a measured amplitude (i.e., measured value). Comparing the measured value with the reference value (step 606) includes using the comparator 616 to compare the reference value (i.e. the reference value amplitude) to the measured value (i.e., the measured amplitude).

If the measured amplitude is about not equal to the reference value amplitude, it will be determined that there is damage to the IC 210 (step 608). Alternately, if the measured amplitude is about equal to the reference value amplitude, it will be determined that there is no damage to the IC 210 (step 608).

In another aspect (for the test ring 290), the tester 610 is an integrated tester (i.e., integrated into the IC). FIG. 6C illustrates a structure for use with the exemplary method of detecting damage 600 to an IC. Enabling the tester 610 includes coupling the first terminal 251 to a ground signal 650 and coupling the second terminal 252 to a known voltage source (V_{dd}) 670, and applying a reference current (I_{ref}) 672 that flows through the plurality of resistors such as 222a-p. The reference value is a reference value voltage equal to the equivalent resistance R_{equivalant} multiplied by the reference current. Measuring a value (i.e., measured value) with the tester (step 604) includes measuring a voltage (measured voltage) at the second terminal 252.

Comparing the measured value with the reference value (step 606) includes comparing the measured voltage at the second terminal 252 with the reference value voltage. Step 606 may be performed by the comparator 616. If the measured voltage at the second terminal 252 is about not equal to the reference value voltage (step 608), there is damage to the IC 210. If the measured voltage at the second terminal 252 is about equal to the reference value voltage (step 608), there is not damage to the IC 210. Step 608 may be performed by the logic 618.

For the test ring 390 illustrated in FIG. 3A, enabling the tester 610 (step 602) includes coupling the measuring device 614 to the first terminal 351 and the second terminal 352 of the test ring 390. In one aspect, enabling the tester 610 may also include storing a reference value in a memory 619. However, it is not necessary to store the reference value in memory 619. The reference value for the test ring 390 (of FIG. 3A) is the equivalent capacitance C_{equivalant} of the plurality of capacitors such as 322a-p. Measuring a value (i.e., measured value) with the tester 610 (step 604) includes measuring a capacitance (i.e., measured capacitance) across the first terminal 351 and the second terminal 352. The measuring device 614 or other known methods or devices may be used to measure the value. Comparing the measured value with the reference value (e.g., C_{equivalant}) (step 606) may be done with the comparator 616 or other known methods or devices.

For step 608, the logic 618 or other known methods or devices may be used for determining that there is damage to the IC 310 (e.g., a crack), if the measured capacitance is about not equal to the reference value (e.g., C_{equivalant}), or determining that there is not damage to the IC 310 if the measured capacitance is about equal to the reference value (e.g., C_{equivalant}). In one aspect where the IC 310 is damaged (e.g., cracked), the measured value would reflect an electrical open in the plurality of capacitors 322a-p coupled in series. Accordingly, the measured value would about not equal to the reference value (e.g., C_{equivalant}), and the logic 618 would determine the IC 310 is damaged. In another aspect where the IC 310 is not damaged, the measured value would about equal to the reference value (e.g., C_{equivalant}), and the logic 618 would determine the IC 310 is not damaged.

For the test ring 490 illustrated in FIG. 4, enabling the tester 610 (step 602) includes coupling the first terminal 451 to the signal generator 612, and coupling the second terminal 452 to the measuring device 614. The signal generator 612 may generate a clock signal that is received as an input by each of the plurality of flip-flops 422a-h. Moreover, enabling the tester 610 further includes initializing each of the plurality of flip-flops 422a-h to a reference value. The reference value may be selected to be any value desired. In one aspect, the reference value may have 8 bits, one bit for each of the eight flip-flops of the plurality of flip-flops 422a-h. For the purposes of this discussion, we will use the reference value of: 10101010 (i.e., 8 bits).

The initialization of each of the plurality of flip-flops 422a-h to the reference value occurs by setting the S or R input of each of the plurality of flip flops 422a-h. According to the known operation of an S—R type of flip-flop, if the S input is set to 1, the output of that flip-flop will be 1, and if the R input is set to 1, the output (is reset) of that flip-flop will be 0. Accordingly (as part of enabling the tester 610): a first flip-flop 422a may have its S input set to 1, a second flip-flop 422b may have its R input set to 1, a third flip-flop 422c may have its S input set to 1, a fourth flip-flop 422d may have its R input set to 1, a fifth flip-flop 422e may have its S input set to 1, a sixth flip-flop 422f may have its R input set to 1, a seventh flip-flop 422g may have its S input set to 1, and the eight flip-flop 422h may have its R input set to 1. In this manner, the plurality of flip-flops 422a-h are initialized to 10101010 respectively (i.e., a pattern of opposite values).

The reference value of 10101010 may be stored in memory 619, or if the tester 610 is an external tester and the testing is being done manually, the reference value need not be stored in memory.

Measuring a value (“measured value”) with the tester 610 (step 604) includes measuring a signal (measured signal) received at the second terminal 452. The measured signal may include at least one bit for each of the plurality of flip-flops 422a-h. The measured signal includes an invalid bit value if there is damage to the IC. The measuring device 614 or other known methods or devices may be used to measure the value. Comparing the measured value with the reference value (e.g., 10101010) (step 606) may be done with the comparator 616.

Determining that there is damage (e.g., a crack) to the IC 400 if the measured value is about not equal to the reference value (e.g., 10101010), or determining that there is not damage to the IC 400 if the measured value is about equal to the reference value (e.g., 10101010) may be performed by the logic 618 or by other methods or devices. In one aspect where the IC 410 is not damaged, the measured value would about equal to the reference value (e.g., 10101010), and the logic 618 would determine the IC 400 is not damaged. In another aspect where the IC 400 is damaged, the damage or crack in the IC 400 would constitute an electrical open in the plurality of flip-flops 422a-h, and the measured value would about not equal to the reference value.

It shall be understood, that because each of the flip-flops 422a-h are initialized, even if the IC 400 is damaged, the measured value will about equal the reference value up until the point of damage. For example, if the IC 400 was cracked between fifth flip-flop 422e and the sixth flip-flop 422f as shown in FIG. 4, the measured value would be “XXXXX010”, where the X's are invalid bit values. So even though in this example, the sixth flip-flop 422f will not able to successfully receive a signal from the fifth flip-flop 422e, the sixth flip-flop 422f will output its originally initialized value of “0” (i.e., the first 0 in the measured value of “XXXXX010”). Likewise, the seventh flip-flop 422g will output its originally initialized value of “1” (i.e., the first 1 in the measured value of “XXXXX010”) and the eighth flip-flop 422f will output its originally initialized value of “0” (i.e., the last bit in the measured value of “XXXXX010”). The first invalid bit value is an output of one of the plurality of flip-flops 422a-h corresponding to a first damaged location of the IC.

The test ring 490 may be used to determine a first damaged location of the IC 400. As discussed previously, each one of the plurality of flip-flops 422a-h corresponds respectively to each one of the eight bits of the reference value (e.g., 10101010). Accordingly, the first damaged location of the IC 400 corresponds to a region near the output of the flip-flop (i.e., one of the plurality of flip-flops 422a-h) that output the first invalid bit value. Continuing with the previous example, if the reference value is “10101010”, and the measured value is “XXXXX010”, the first damaged location of the IC 400 occurs after the fifth flip-flop 422f since it is the fifth flip-flop that output the first invalid bit value.

In another aspect, where the tester 610 is an integrated tester, the method for detecting damage 600 may include the following. An up-down counter (not shown) may be coupled to the second terminal 452. The up-down counter may be part of the measuring device 614 of the tester 610. At step 602, the tester is enabled by: initializing the up-down counter to zero, applying a number of clock cycles to the test ring 490 where the number of clock cycles is equal to the number of flip-flops (e.g. if there are eight flip-flops 422a-h, eight clock cycles would be applied), and by initializing each of the flip-flops 422a-h so that all S inputs=1, and all R inputs=1 (as previously discussed. Measuring a value with the tester 610 (step 604) includes using the up-down counter to count up by 1 if the tester 610 receives a 1 from the second terminal 452, and to count down by 1 (i.e., subtract 1) if the tester receives a 0 from the second terminal 452. In other words, the measured value is the output of the up-down counter.

At step 606, the measured value is compared with the reference value. In one aspect, where the plurality of flip-flops is initialized to 10101010, the reference value may be equal to 0 (i.e., 1−1+1−1+1−1+1−1=0). In other words, the reference value is the calculated value of the up-down counter based on the number of flip-flops (e.g., the plurality of flip-flops 422a-h has 8 flip-flops). At step 608, it is determined that there is no damage to the IC if the measured value at the up-down counter is about equal to the reference value (e.g., 0). At step 608, it is determined that there is damage to the IC if the measured value at the up-down counter is about not equal to the reference value 0. Returning to the previous example where there is damage to the IC 400 after the fifth flip-flop 422e, the measured value would equal “−1” (i.e., −1+1−1). Therefore, the method of 600 would determine that there is damage to the IC because the measured value of “−1” does not equal the reference value of “0”.

For the test ring 590 illustrated in FIG. 5, enabling the tester 610 (step 602) includes coupling the first terminal 551 to the signal generator 612, and the second terminal 552 to the measuring device 614. As part of enabling the tester 610, a “0” may be applied at the first terminal 551 by the signal generator 612. By applying the “0” an expected output of the second terminal is obtained. As an example, by applying “0” to the first inverter 510a, the expected output of the second terminal, i.e., the reference value is 10101010 (one bit for each inverter). The reference value may optionally be stored in memory 619.

Measuring a value (“measured value”) with the tester 610 (step 604) includes measuring a signal at the second terminal 552. The measuring device 614 or other known methods or devices may be used to measure the value. Comparing the measured value with the reference value (e.g., 10101010) (step 606) may be done with the comparator 616.

The logic 618 or other known methods or devices may be used for determining that there is damage to the IC 500 if the measured value is about not equal to the reference value (e.g., 10101010), or determining that there is not damage to the IC 500 if the measured value is about equal to the reference value (e.g., 10101010). If the IC 500 is damaged, the damage or crack would constitute an electrical open in the plurality of inverters 522a-h coupled in series. Accordingly, the measured value would about not equal to the reference value (e.g., 10101010), and the logic 618 would determine the IC 500 is damaged.

### Exemplary Electronic Devices

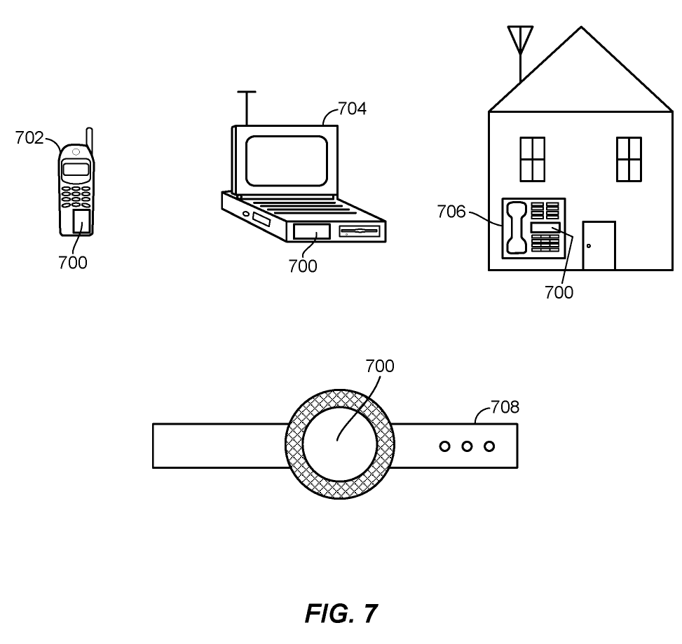

FIG. 7 illustrates various electronic devices that may be integrated with any of the aforementioned substrate, integrated device, semiconductor device, integrated circuit, die, interposer, or package. For example, a mobile phone device 702, a laptop computer device 704, a fixed location terminal device 706, a wearable device 708 may include an integrated device 700 as described herein. The integrated device 700 may be, for example, any of the substrate, integrated circuits, dies, integrated devices, integrated device packages, integrated circuit devices, device packages, integrated circuit (IC) packages, package-on-package devices described herein. The devices 702, 704, 706, 708 illustrated in FIG. 7 are merely exemplary. Other electronic devices may also feature the integrated device 700 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watch, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIG. 2A through FIG. 6B may be rearranged and/or combined into a single component, process, feature or function or embodied in several components, proceses, or functions. Additional elements, components, processes, and/or functions may also be added without departing from the disclosure. It should also be noted that FIG. 2A through FIG. 6B and its corresponding description in the present disclosure is not limited to substrates. In some implementations, FIG. 2A through FIG. 6B and its corresponding description may be used to manufacture, create, provide, and/or produce integrated devices. In some implementations, a device may include a die, an integrated device, a die package, an integrated circuit (IC), a device package, an integrated circuit (IC) package, a wafer, a semiconductor device, a package on package (PoP) device, and/or an interposer.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling between two objects. For example, if object A physically touches object B, and object B touches object C, then objects A and C may still be considered coupled to one another—even if they do not directly physically touch each other. The term “traverse” as used herein, means to go across and includes going all the way across an object or partially across an object.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed. The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

What is claimed is:

1. An apparatus comprising:
a test ring around a periphery of an integrated circuit (IC), the test ring further comprising:
a first terminal;
a second terminal; and
a first circuit element, wherein the first terminal is coupled to the first circuit element, and the first circuit element is coupled to the second terminal, wherein the first terminal, the first circuit element and the second terminal are coupled together in series.

2. The apparatus of claim 1, wherein the first circuit element comprises a first resistor.

3. The apparatus of claim 2, wherein the first resistor is selected from the group consisting of a well-resistor, a polysilicon resistor, and a metal resistor.

4. The apparatus of claim 2, further comprising:
a second resistor, the second resistor coupled in series with the first resistor, the first terminal and the second terminal.

5. The apparatus of claim 4, further comprising
the first resistor including a first metal and a second metal located in a first lateral plane, and coupled to a first isolation region, the first and second metal located over a substrate; and
the second resistor including a third metal and a fourth metal located in the first lateral plane, and coupled to a second isolation region, the third metal and fourth metal located over a substrate.

6. The apparatus of claim 5, wherein the first metal and the second metal are located over a doped region in a first well, and the third metal and the fourth metal are located over a doped region in a second well.

7. The apparatus of claim 1, wherein the first circuit element comprises a first capacitor.

8. The apparatus of claim 7, wherein the first capacitor is selected from the group consisting of a junction capacitor, a MOS capacitor and a metal capacitor.

9. The apparatus of claim 7, further comprising:
a second capacitor, the second capacitor coupled in series with the first capacitor, the first terminal and the second terminal.

10. The apparatus of claim 9, further comprising
the first capacitor including a first metal coupled to a first oppositely doped area, and a second metal coupled to a first isolation region, the first oppositely doped area located in the first isolation region; and
the second capacitor including a third metal coupled to a second oppositely doped area, and a fourth metal coupled to a second isolation region, the second oppositely doped area located in the second isolation region, the first metal, the second metal, the third metal, and the fourth metal over a substrate of the IC.

11. The apparatus of claim 1, wherein the first circuit element is a passive device.

12. The apparatus of claim 1, wherein the first circuit element comprises a first flip-flop.

13. The apparatus of claim 12, wherein the first flip-flop is selected from the group consisting of an S-R flip-flop, a D flip-flop, a T flip-flop and a JK flip-flop.

14. The apparatus of claim 1, wherein the first circuit element is integrated into the IC.

15. The apparatus of claim 1, wherein the apparatus is configured for coupling to a tester that is integrated into the IC.

16. The apparatus of claim 15, wherein the tester includes a signal generator, a measuring device, a comparator, a logic, or a memory, or a combination thereof.

17. The apparatus of claim 1, further comprising:
wherein the test ring includes a measurable value;
wherein the test ring includes a reference value;
wherein the IC includes a crack if the measurable value is about not equal to the reference value.

18. The apparatus of claim 1, wherein the test ring is located in a seal ring, the seal ring is located around a periphery of the IC.

19. The apparatus of claim 1, wherein the apparatus is incorporated into a device selected from a group consisting of a music player, a video player, an entertainment unit, a navigation device, a communications device, a mobile device, a mobile phone, a smart phone, a personal digital assistant, a fixed location terminal or server, a tablet computer, a wearable computing device, and a laptop computer.

20. A method for detecting damage to the integrated circuit, comprising:
enabling a tester that is coupled to a test ring in a periphery of an integrated circuit (IC), wherein the test ring comprises a first circuit element coupled in series to a first terminal and a second terminal;
measuring a value with the tester;
comparing the measured value with a reference value; and
determining that there is damage to the IC if the measured value is about not equal to the reference value, or determining that there is not damage to the IC if the measured value is about equal to the reference value.

21. The method of claim 20, further comprising:
wherein the first circuit element includes a first resistor;
wherein the reference value is equal to an equivalent resistance of the first resistor;
wherein measuring the value includes measuring a resistance, that is the measured resistance, between the first terminal and the second terminal; and
determining that there is damage to the IC if the measured resistance is about not equal to the equivalent resistance, or determining that there is not damage to the IC if the measured resistance is about equal to the equivalent resistance.

22. The method of claim 20, further comprising:
wherein the first circuit element includes a first resistor;
wherein enabling the tester includes applying a sinusoidal signal to the first terminal, the sinusoidal signal includes a reference value amplitude;
wherein measuring the value includes measuring a signal at the second terminal including a measured amplitude; and
determining that there is damage to the IC if the measured amplitude is about not equal to the reference value amplitude, or determining that there is not damage to the IC if the measured amplitude about equals the reference value amplitude.

23. The method of claim 20, further comprising:
wherein the first circuit element includes a first resistor;
wherein enabling the tester includes coupling the first terminal to a ground signal, and applying a reference current that flows through the first resistor;
wherein the reference value is a reference value voltage equal to an equivalent resistance of the first resistor multiplied by the reference current;
wherein measuring a value includes measuring a voltage, that is the measured voltage, at the second terminal; and
determining that there is damage to the IC if the measured voltage is about not equal to the reference value voltage, or determining that there is not damage to the IC if the measured voltage about equals the reference value voltage.

24. The method of claim 20, further comprising:
wherein the first circuit element includes a first capacitor;
wherein the reference value is equal to an equivalent capacitance of the first capacitor; and
wherein measuring the value includes measuring a capacitance, that is the measured capacitance, between the first terminal and the second terminal; and
determining that there is damage to the IC if the measured capacitance is about not equal to the equivalent capacitance, or determining that there is not damage to the IC if the measured capacitance about equals the equivalent capacitance.

25. The method of claim 20, further comprising:
wherein the first circuit element is a first flip-flop;
wherein enabling the tester includes setting the first flip-flop to a first reference value and applying a clock to the first flip-flop; and
wherein measuring a value includes measuring a signal, that is the measured signal, at the second terminal;
determining that there is damage to the IC if the measured signal is about not equal to the first reference value, or determining that there is not damage to the IC if the measured signal about equals the first reference value.

26. The method of claim 25, further comprising:
a second flip-flop, wherein an input of the first flip-flop is coupled to the first terminal and an output of the first flip-flop is coupled to the second flip-flop, and where an output of the second flip-flop is coupled to the second terminal;
wherein enabling the tester includes setting the second flip-flop to a second reference value and applying the clock to the second flip-flop; and
wherein the measured signal includes a first bit and a second bit.

27. The method of claim 26, wherein the measured signal includes an invalid bit value if there is damage to the IC, wherein the invalid bit value is an output of one of the first flip-flop or second flip-flop corresponding to a damaged location on the IC.

28. The method of claim 25, further comprising:
an up-down counter coupled to the second terminal;
wherein a second reference value is equal to a calculated value for the up-down counter;
wherein the measured signal includes the output of the up-down counter; and
determining that there is damage to the IC if the output of the up-down counter is about not equal to the second reference value, or determining that there is not damage to the IC if the output of the up-down counter about equals the second reference value.

29. The method of claim 20, further comprising:
wherein the first circuit element is a first inverter;
wherein enabling the tester includes applying a first bit to the first inverter;
wherein the reference value is an expected output of the second terminal;
wherein measuring the value includes measuring a signal, that is a measured signal, at the second terminal; and
determining that there is damage to the IC if the measured signal is about not equal to the reference value, or determining that there is not damage to the IC if the measured signal is about equal to the reference value.

30. An apparatus comprising:
a test ring around a periphery of an integrated circuit (IC), the test ring further comprising:
a first terminal;
a second terminal;
a first means for detecting damage to the IC, coupled in series with the first terminal and the second terminal.

31. The apparatus of claim 30, wherein the first means for detecting damage to the IC includes a first resistor.

32. The apparatus of claim 30, wherein the first means for detecting damage to the IC includes a first capacitor.

33. The apparatus of claim 30, wherein the first means for detecting damage to the IC includes a first flip-flop.

34. The apparatus of claim 33, wherein the first means for detecting damage to the IC includes means for determining a first damaged location of the IC.

35. The apparatus of claim 30, wherein the first means for detecting a crack in the IC includes a first inverter.
